(19) United States
(12) Patent Application Publication
(10) Pub. No.: US 2023/0402344 A1
(43) Pub. Date: Dec. 14, 2023

(54) HEAT SPREADER FOR USE WITH A SEMICONDUCTOR DEVICE

(71) Applicant: STATS ChipPAC Pte. Ltd., Singapore (SG)

(72) Inventors: SooHan PARK, Incheon (KR); HyeSun KIM, Incheon (KR); KyungEun KIM, Incheon (KR); YouJin SHIN, Incheon (KR)

(21) Appl. No.: 18/330,347

(22) Filed: Jun. 6, 2023

(30) Foreign Application Priority Data
Jun. 10, 2022 (CN) 202210656135.8

(51) Int. Cl. H01L 23/367; H01L 23/00; H01L 21/50

(52) U.S. Cl. CPC H01L 23/3675; H01L 24/32; H01L 21/50; H01L 2224/32245

(57) ABSTRACT

Provided is a heat spreader for use with a semiconductor device comprising a substrate and at least one semiconductor die mounted on the substrate. The heat spreader comprises: a main body defining a space for receiving the at least one semiconductor die; and two foot supports extending downward from the main body and opposite to each other, each of the foot supports defining a slot at its inner surface, wherein the slots of the two foot supports are aligned with each other. When the heat spreader is mounted with the semiconductor device, the slots prevent the substrate from moving closer to or away from the main body.

### TECHNICAL FIELD

The present application generally relates to semiconductor technologies, and more particularly, to a heat spreader for use with a semiconductor device.

### BACKGROUND OF THE INVENTION

Semiconductor devices are commonly found in modern electronic products, which perform a wide range of functions, such as signal processing, high-speed calculations, transmitting and receiving electromagnetic signals, controlling electronic devices, and creating visual images for television displays. An integrated circuit can be fabricated within a semiconductor die. The semiconductor die can also be referred to as a chip, and the die can be a so-called “flip-chip”. A flip-chip has a surface that includes conductive protrusions, which can be referred to as “bumps”.

During operation, the integrated circuits in the semiconductor die can generate heat which requires a heat spreader to transfer from the die to a surrounding environment. A conventional heat spreader includes a foot portion and a slope sidewall portion for attaching the heat spreader onto a substrate where the semiconductor die is mounted, and thus a mounting space is required on the substrate for the foot portion and slope sidewall portion.

However, it is desired to mount more and more components on the substrate, such as a big semiconductor die and small discrete components. For example, FIG. 1 shows a semiconductor device 100 that includes a big semiconductor die 101 and lots of discrete components 102 mounted on a substrate 103 and surrounding the big semiconductor die 101. As can be seen from FIG. 1, some of the discrete components 102 may occupy the space for mounting the foot portion 104 and the slope sidewall portion 105 of the conventional heat spreader, therefore the space for the heat spreader is limited.

Therefore, a need exists for an improved heat spreader for use with a semiconductor device.

### SUMMARY OF THE INVENTION

An objective of the present application is to provide a heat spreader for use with a semiconductor device, with an improved layout design of the semiconductor device.

According to one aspect of the present application, a heat spreader for use with a semiconductor device comprising a substrate and at least one semiconductor die mounted on the substrate is provided. The heat spreader comprises: a main body defining a space for receiving the at least one semiconductor die; and two foot supports extending downward from the main body and opposite to each other, each of the foot supports defining a slot at its inner surface, wherein the slots of the two foot supports are aligned with each other. When the heat spreader is mounted with the semiconductor device, the slots prevent the substrate from moving closer to or away from the main body.

According to another aspect of the present application, a semiconductor assembly is provided. The semiconductor assembly comprises: a semiconductor device comprising a substrate and at least one semiconductor die mounted on the substrate; and a heat spreader mounted with the semiconductor device. The heat spreader comprises: a main body defining a space for receiving the at least one semiconductor die; and two foot supports extending downward from the main body and opposite to each other, each of the foot supports defining a slot at its inner surface, wherein the slots of the two foot supports are aligned with each other. The slots prevent the substrate from moving closer to or away from the main body.

According to another aspect of the present application, A method for making a semiconductor assembly is provided. The method comprises: providing a semiconductor device, wherein the semiconductor device comprises a substrate and at least one semiconductor die mounted on the substrate; providing a heat spreader, wherein the heat spreader comprises a main body defining a space for receiving the at least one semiconductor die, and two foot supports extending downward from the main body and opposite to each other, each of the foot supports defining a slot at its inner surface, wherein the slots of the two foot supports are aligned with each other; and inserting the substrate into the slots, wherein the slots prevent the substrate from moving closer to or away from the main body.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 illustrates a top view of a conventional semiconductor device.

FIG. 2 illustrates a perspective view of a heat spreader according to an embodiment of the present application.

FIG. 3A illustrates a perspective view of a semiconductor assembly according to an embodiment of the present application.

FIG. 3B shows a cross-sectional view of the semiconductor assembly shown in FIG. 3A.

FIG. 3C shows a top view of the semiconductor assembly shown in FIG. 3A.

FIG. 4A illustrates a cross-sectional view of a semiconductor assembly according to another embodiment of the present application.

FIG. 4B shows a top view of the semiconductor assembly shown in FIG. 4A.

FIG. 5 illustrates a cross-sectional view of a semiconductor assembly according to another embodiment of the present application.

FIG. 6 illustrates a cross-sectional view of a semiconductor assembly according to another embodiment of the present application.

FIG. 7 illustrates a cross-sectional view of a semiconductor assembly according to another embodiment of the present application.

FIG. 8 illustrates a flow chart of a method for making a semiconductor assembly according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

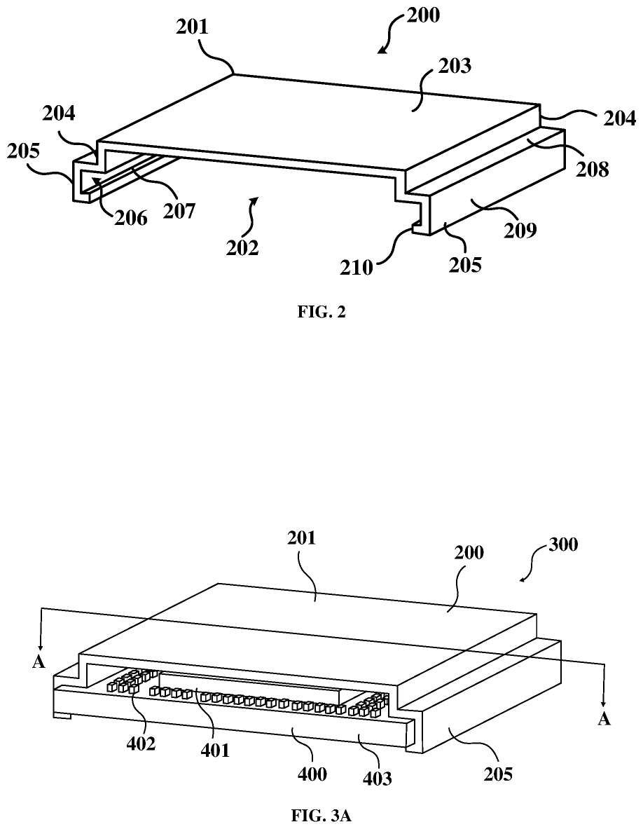

FIG. 2 illustrates a perspective view of a heat spreader 200 according to an embodiment of the present application. The heat spreader 200 may be mounted on a substrate of a semiconductor device to provide heat dissipation for certain electronic components on the substrate, such as a semiconductor die.

As shown in FIG. 2, the heat spreader 200 includes a main body 201. The main body 201 defines a space 202 for receiving at least one semiconductor die of the semiconductor device, when the heat spreader 200 is assembled with the semiconductor device. In particular, the main body 201 may include a top cover 203 and two side walls 204 extending downward from the top cover 203. The top cover 203 and the two side walls 204 together define the space 202 for receiving the at least one semiconductor die. In some embodiments, the top cover 203 is formed as a flat plate that can easily contact a semiconductor die having a flat top surface. In some other embodiments, the top cover 203 may be formed in any other desired shapes and structures, depending on the shape and structure of the semiconductor die or dices. For example, if two or more semiconductor dice with different thicknesses require heat dissipation by the heat spreader 200, the top cover 203 can include two or more regions each having a depth corresponding to the thickness of one of the two or more semiconductor dice thereunder.

The heat spreader 200 further includes two foot supports 205 extending downward from the main body 201, which are opposite to each other. As can be seen, the two foot supports 205 each define a slot 206 at its inner surface 207. The slots 206 respectively defined by the two foot supports 205 are aligned with each other, such that two opposite edges of a substrate of a semiconductor device can be received within the slots, respectively. For example, the substrate of the semiconductor device can slide into the slots 206. In some embodiments, the two slots define a plane which is substantially in parallel with the top cover 203. Still referring to FIG. 2, each foot support 205 may include a step 208 extending outward from the main body 201, a side wall 209 extending downward from the step 208 and a bottom protrusion 210 extending inward from the side wall 209. The step 208, the side wall 209 and the bottom protrusion 210 on a foot support 205 together define the slot 206.

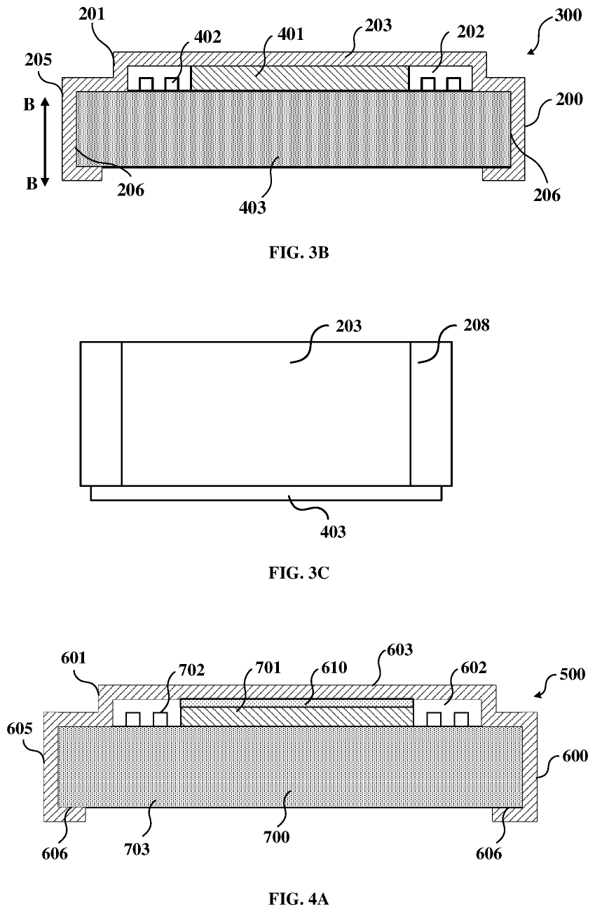

FIG. 3A illustrates a perspective view of a semiconductor assembly 300 that includes the heat spreader 200 shown in FIG. 2 and a semiconductor device 400. FIG. 3B shows a cross-sectional view of the semiconductor assembly 300 along line A-A in FIG. 2, and FIG. 3C shows a top view of the semiconductor assembly 300.

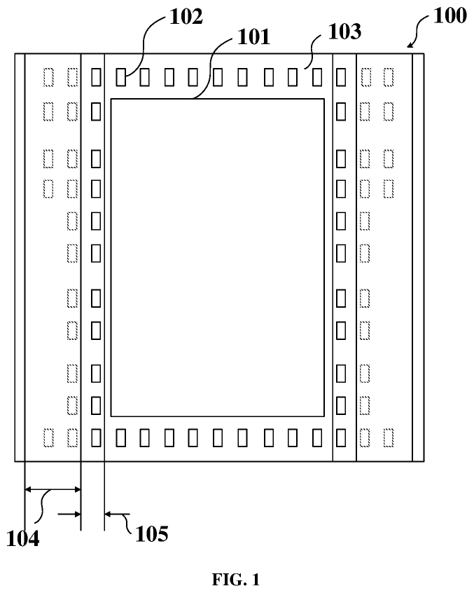

As shown in FIGS. 3A to 3C, the semiconductor device 400 may have a structure similar as the semiconductor device 100 shown in FIG. 1, for example, the semiconductor device 400 may include a semiconductor die 401 and various smaller electronic components 402 mounted on a substrate 403. The electronic components 402 may have a size much smaller than that of the semiconductor die 401, and surround the semiconductor die 401. Generally, the semiconductor die 401 may be integrated therewithin a complicated circuitry structure which requires heat dissipation. The smaller electronic components 402 may not generate significant heat during operation and thus may not require heat dissipation by the heat spreader 200. In some embodiments, the components of the semiconductor device 400 may have a layout different than that shown in FIGS. 3A to 3C. For example, more than one semiconductor dice may be mounted on the substrate 403, or a reduced number of smaller electronic components may surround the semiconductor die or dice of the semiconductor device 400.

As can be seen from FIGS. 3A and 3B, when the heat spreader 200 is attached with the substrate 403, the semiconductor die 401 can be received within the space 202 defined by the main body 201 of the heat spreader 200, and the semiconductor die 401 can be in contact with the top cover 203 of the main body 201. In this way, the heat generated by the semiconductor die 401 can be transferred from the semiconductor die 401 to the exterior environment through the heat spreader 200. In general, the heat spreader 200 is made of a thermally conductive material such as metal, which may be also electrically conductive. Accordingly, in some embodiments, the edges of the substrate 403 which are received within the slots 206 of the foot supports 205 may not include any conductive patterns or bumps to avoid short-circuit issue.

The two foot supports 205 are disposed on two opposite sides of the main body 201, leaving the other two sides of the main body 201 open. Accordingly, the substrate 403 can be inserted through an opening under the top cover 201 and further into the two slots 206 respectively defined by the two foot supports 205 of the heat spreader 200. The width of the slots 206 generally matches the thickness of the substrate 403 of the semiconductor device 400, therefore when the semiconductor device 400 is mounted within the heat spreader 200, the slots 206 defined by the two foot supports 205 of the heat spreader 200 can prevent the substrate 403 from moving closer to or away from the main body 201 of the heat spreader 200. That is, the movement of the substrate 403 along line BB is prevented by the engagement between the slots 206 and the substrate 403. In some embodiments, one or more fasteners may be further disposed on the heat spreader 200 and the substrate 403 to avoid the further movement between them. For example, two screw holes can be constructed on the bottom protrusion and the edge of the substrate 403, and therefore, when the two screw holes are aligned with each other, a screw or a bolt may be screwed into the two screw holes. Furthermore, although it is shown in FIG. 3C that the substrate 403 is not fully accommodated under the top cover 203, in some other embodiments, the substrate 403 can be fully accommodated under the top cover 203.

As can be seen from FIGS. 3A to 3C, since the foot supports 205 of the heat spreader 200 are attached to the edges of the substrate 403, rather than on somewhere on the substrate 403 (e.g., a periphery of the semiconductor die 401), less space on the substrate 403 may be occupied by the heat spreader 200. In this way, there may be more space for mounting the semiconductor die 401 or other electronic components of the semiconductor device 400.

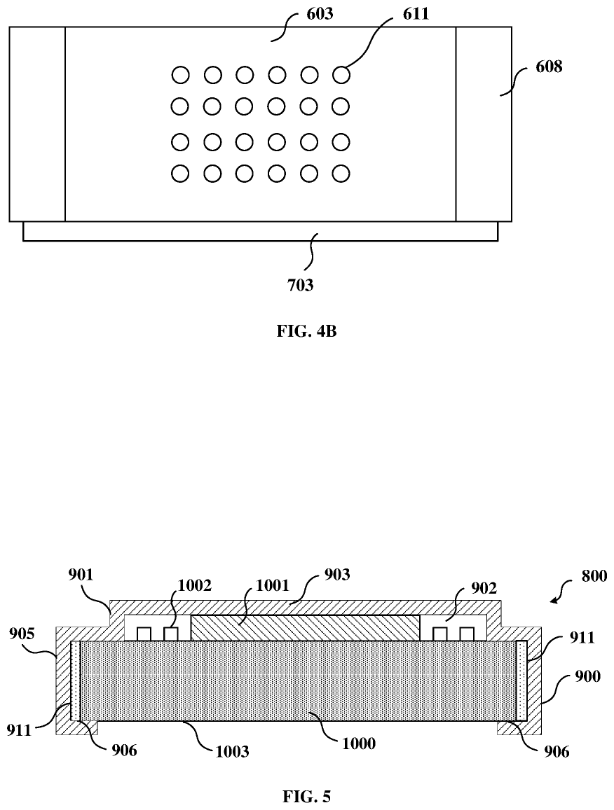

FIG. 4A illustrates a cross-sectional view of a semiconductor assembly 500 that includes a heat spreader 600 and a semiconductor device 700, and FIG. 4B shows a top view of the semiconductor assembly 500 shown in FIG. 4A.

As shown in FIGS. 4A and 4B, the heat spreader 600 includes a main body 601 defining a space 602 for receiving a semiconductor die 701 of the semiconductor device 700, and two foot supports 605 each defining a slot 606. The slots 606 in combination can be used to receive and mount a substrate 703 of the semiconductor device 700. Different from the semiconductor assembly 300 shown in FIGS. 3A to 3C, a top cover 603 of the main body 601 is not directly in contact with the semiconductor die 701, i.e., a thickness of the semiconductor die 701 is smaller than a depth of the space 602. Rather, a thermally conductive material 610 can be filled within a gap formed between the top cover 603 and a top surface of the semiconductor die 701, to ensure desired thermal contact between the heat spreader 600 and the semiconductor die 701. In some embodiments, the top cover 603 may include a plurality of holes 611. Through the holes 611, the thermally conductive material can be applied into the gap between the top cover 603 and the semiconductor die 701, which later can be solidified as a thermally conductive layer 610. For example, the thermally conductive material may be a fluid material at room temperature or at a higher temperature (e.g., 60 centi-degrees) so that it can be applied between the top cover 603 and the semiconductor die 701 at room temperature through the holes 611, while a curing process can then be performed on the semiconductor assembly to solidify the thermally conductive layer 610. In some other embodiments, the thermally conductive material can be solidified through a radiation process such as through ultraviolet radiation. In a preferred embodiment, the array of holes 611 may substantially overlap with the semiconductor die 701 when the semiconductor device 700 is assembled with the heat spreader 600.

With the later filled thermally conductive layer 610, the semiconductor die 701 may not directly contact the top cover 603 when the semiconductor device 700 is inserted into the heat spreader 600. In this way, undesired damages to the surface of the semiconductor die 701 due to the friction between the semiconductor die 701 and the top cover 603 can be avoided during the assembling process of the semiconductor assembly 500, and the thermal performance of the semiconductor assembly may not be degraded.

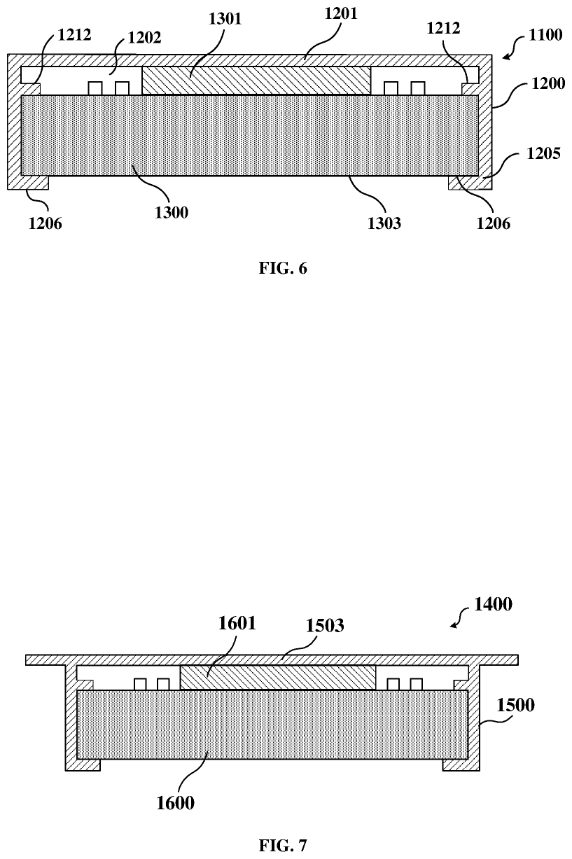

FIG. 5 illustrates a cross-sectional view of a semiconductor assembly 800 that includes a heat spreader 900 and a semiconductor device 1000 according to another embodiment of the present application.

As shown in FIG. 5, the structure of the semiconductor assembly 800 is similar as the structure of the semiconductor assembly 300 shown in FIGS. 3A-3C. In particular, the heat spreader 900 includes a main body 901 defining a space 902 for receiving a semiconductor die 1001 of the semiconductor device 1000 and two foot supports 905 each defining a slot 906. The slots 906 can be used to receive a substrate 1003 of the semiconductor device 1000.

Different from the semiconductor assembly 300 shown in FIGS. 3A-3C, an adhesive layer 911 is formed in each of the slots 906. With the adhesive layer 911, the semiconductor device 1000 can be better secured to the heat spreader 900. In one embodiment, the adhesive layer 911 may be formed in each of the slots 906 in advance to inserting the semiconductor device 1000 into the heat spreader 900. The viscidity of the adhesive layer 911 may be activated through heating. Therefore, the adhesive layer 911 may have no or a relatively low viscidity to avoid blocking the semiconductor device 1000 from being inserted into the heat spreader 900, while after the semiconductor device 1000 has been inserted into the heat spreader 900, the adhesive layer 911 can be heated to activate its viscidity so that the semiconductor device 1000 can be better secured to the heat spreader 900. In some other embodiment, the adhesive layer 911 may be formed after the semiconductor device 1000 has been inserted into the heat spreader 900, for example, by filling an adhesive material within a gap inside the slot 906. The adhesive layer 911 may be heated or processed in other suitable manners to improve its viscidity and adhesivity.

FIG. 6 illustrates a cross-sectioning view of a semiconductor assembly 1100 that includes a heat spreader 1200 and a semiconductor device 1300, according to another embodiment of the present application.

As shown in FIG. 6, the structure of the semiconductor assembly 1100 is generally similar as the that of the semiconductor assembly 300 shown in FIGS. 3A-3C. In particular, the heat spreader 1200 includes a main body 1201 defining a space 1202 for receiving a semiconductor die 1301 of the semiconductor device 1300 and two foot supports 1205 each defining a slot 1206. The slots 1206 can be used to receive a substrate 1303 of the semiconductor device 1300. Different from the heat spreader 200 shown in FIGS. 3A-3C, the two foot supports 1205 each include a top protrusion 1212 extending inward from a side wall of the main body 1201. The top protrusions 1212 and the foot supports 1205 together define the two slots 1206.

In some embodiments, the heat spreader 1200 may be made by a molding process. Accordingly, the heat spreader 1200 can be formed with various other shapes or structures. FIG. 7 illustrates a cross-sectional view of a semiconductor assembly 1400 according to another embodiment of the present application, which includes a heat spreader 1500 with a different main body.

As shown in FIG. 7, the semiconductor assembly 1400 includes the heat spreader 1500 and a semiconductor device 1600. Different from the heat spreader 1200 as shown in FIG. 6, the heat spreader 1500 has a larger top cover 1503. The enlarged top cover 1503 can further improve heat dissipation from a semiconductor die 1601 of the semiconductor device 1600 to the exterior environment.

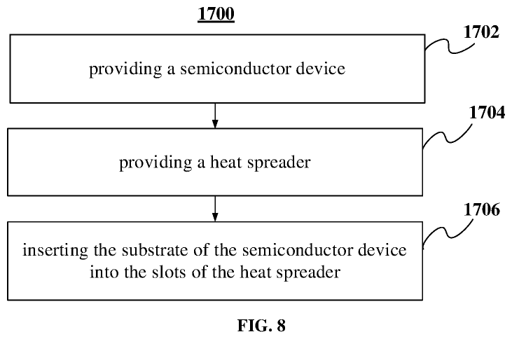

FIG. 8 illustrates a flow chart of a method 1700 for making a semiconductor assembly according to an embodiment of the present application. The semiconductor assembly may has a structure similar as the semiconductor assembly 300, semiconductor assembly 500, semiconductor assembly 800, semiconductor assembly 1100 and semiconductor assembly 1400 shown in FIGS. 3-7, respectively.

The method 1700 starts at a step 1702 of providing a semiconductor device is provided. The semiconductor device includes a substrate and at least one semiconductor die mounted on the substrate. The semiconductor device may have a structure similar as the semiconductor devices 100, 400, 1000, 1300 or 1600 as shown in FIGS. 1 and 3-7, respectively.

The method 1700 further includes a step 804 of providing a heat spreader. The heat spreader may include a main body defining a space for receiving the at least one semiconductor die; and two foot supports extending downward from the main body and opposite to each other, each of the foot supports defining a slot at its inner surface. The slots of the two foot supports are aligned with each other. In some embodiments, the heat spreader may have a structure similar as the heat spreader 200, 600, 900, 1200 or 1500 as shown in FIGS. 2-7, respectively.

The method 800 include a step 806: the substrate is inserted into the slots, wherein the slots prevent the substrate from moving closer to or away from the main body. Therefore, the semiconductor assembly is formed.

The discussion herein included numerous illustrative figures that showed various portions of a heat spreader for use with a semiconductor component and method of manufacturing thereof. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A heat spreader for use with a semiconductor device comprising a substrate and at least one semiconductor die mounted on the substrate, the heat spreader comprising:
a main body defining a space for receiving the at least one semiconductor die; and
two foot supports extending downward from the main body and opposite to each other, each of the foot supports defining a slot at its inner surface, wherein the slots of the two foot supports are aligned with each other;
wherein when the heat spreader is mounted with the semiconductor device, the slots prevent the substrate from moving closer to or away from the main body.

2. The heat spreader according to claim 1, wherein the main body comprises:
a top cover in thermal contact with the semiconductor die; and
two side walls extending downward from the top cover;
wherein the top cover and the two side walls define the space for receiving the semiconductor die.

3. The heat spreader according to claim 2, wherein the top cover is in thermal contact with the semiconductor die through a thermally conductive layer.

4. The heat spreader according to claim 3, wherein the main body comprises a plurality of holes disposed at the top cover, wherein the thermally conductive layer is applied between the top cover and the semiconductor die through the plurality of holes.

5. The heat spreader according to claim 1, wherein the two foot supports each comprises:
a step extending outward from the main body;
a side wall extending downward from the step; and
a bottom protrusion extending inward from the side wall;
wherein the step, the side wall and the bottom protrusion define the slot.

6. The heat spreader according to claim 1, further comprising an adhesive layer formed in each of the two slots for securing the semiconductor device.

7. A semiconductor assembly, comprising:
a semiconductor device comprising a substrate and at least one semiconductor die mounted on the substrate; and
a heat spreader mounted with the semiconductor device, comprising:
a main body defining a space for receiving the at least one semiconductor die; and
two foot supports extending downward from the main body and opposite to each other, each of the foot supports defining a slot at its inner surface, wherein the slots of the two foot supports are aligned with each other;
wherein the slots prevent the substrate from moving closer to or away from the main body.

8. The semiconductor assembly according to claim 7, wherein the main body comprises:
a top cover in thermal contact with the semiconductor die; and
two side walls extending downward from the top cover;
wherein the top cover and the two side walls define the space for receiving the semiconductor die.

9. The semiconductor assembly according to claim 8, wherein the top cover is in thermal contact with the semiconductor die through a thermally conductive layer.

10. The semiconductor assembly according to claim 9, wherein the main body comprises a plurality of holes disposed at the top cover, wherein the thermally conductive layer is applied between the top cover and the semiconductor die through the plurality of holes.

11. The semiconductor assembly according to claim 7, wherein the two foot supports each comprises:
a step extending outward from the main body;
a side wall extending downward from the step; and
a bottom protrusion extending inward from the side wall;
wherein the step, the side wall and the bottom protrusion define the slot.

12. The heat spreader according to claim 7, wherein the heat spreader further comprises an adhesive layer formed in each of the two slots for securing the semiconductor device to the heat spreader.

13. A method for making a semiconductor assembly, comprising:
providing a semiconductor device, wherein the semiconductor device comprises a substrate and at least one semiconductor die mounted on the substrate;
providing a heat spreader, wherein the heat spreader comprises:
a main body defining a space for receiving the at least one semiconductor die; and
two foot supports extending downward from the main body and opposite to each other, each of the foot supports defining a slot at its inner surface, wherein the slots of the two foot supports are aligned with each other; and
inserting the substrate into the slots, wherein the slots prevent the substrate from moving closer to or away from the main body.

14. The method according to claim 13, wherein the main body comprises:
a top cover in thermal contact with the semiconductor die; and
two side walls extending downward from the top cover;
wherein the top cover and the two side walls define the space for receiving the semiconductor die.

15. The method according to claim 14, further comprising applying a thermally conductive material between the top cover and the semiconductor die to form a thermally conductive layer therebetween.

16. The method according to claim 15, wherein the thermally conductive material is applied between the top cover and the semiconductor die through a plurality of holes disposed at the top cover.

17. The method according to claim 13, wherein the two foot supports each comprises:
a step extending outward from the main body;
a side wall extending downward from the step; and
a bottom protrusion extending inward from the side wall;
wherein the step, the side wall and the bottom protrusion define the slot.

18. The method according to claim 13, further comprising applying an adhesive layer to each of the two slots for securing the semiconductor device to the heat spreader.
